(19) United States
(12) Patent Application Publication
(10) Pub. No.: US 2023/0246086 A1
(43) Pub. Date: Aug. 3, 2023

(54) WIDE BAND GAP TRANSISTOR WITH NANOLAMINATED INSULATING GATE STRUCTURE AND PROCESS FOR MANUFACTURING A WIDE BAND GAP TRANSISTOR

(71) Applicant: STMICROELECTRONICS S.r.l., Agrate Brianza (IT)

(72) Inventors: Ferdinando IUCOLANO, Gravina di Catania (IT); Raffaella LO NIGRO, Sant'Agata li Battiati (IT); Emanuela SCHILIRÒ, Bronte (IT); Fabrizio ROCCAFORTE, Mascalucia (IT)

(73) Assignee: STMICROELECTRONICS S.r.l., Agrate Brianza (IT)

(21) Appl. No.: 18/156,120

(22) Filed: Jan. 18, 2023

(30) Foreign Application Priority Data
Jan. 28, 2022 (IT) 102022000001478

(51) Int. Cl. H01L 29/51; H01L 29/20; H01L 29/205; H01L 29/778; H01L 21/02; H01L 21/28; H01L 29/40; H01L 29/66

(52) U.S. Cl. CPC H01L 29/513; H01L 21/022; H01L 21/0228; H01L 21/02178; H01L 21/02181; H01L 21/28185; H01L 29/205; H01L 29/401; H01L 29/517; H01L 29/2003; H01L 29/7786; H01L 29/66462

(57) ABSTRACT

The present disclosure is directed to a wide band gap transistor that includes a semiconductor structure, having at least one wide band gap semiconductor layer of gallium nitride or silicon carbide, an insulating gate structure and a gate electrode, separated from the semiconductor structure by the insulating gate structure. The insulating gate structure contains a mixture of aluminum, hafnium and oxygen.

### BACKGROUND

### Technical Field

The present disclosure relates to a wide band gap transistor with nanolaminated insulating gate structure and to a process for manufacturing a wide band gap transistor.

### Description of the Related Art

Semiconductor materials, which have a Wide Band Gap (WBG), in particular, which have an energy value Eg of the band gap being greater than 1.1 eV, low on-state resistance (RON), a high value of thermal conductivity, high operating frequency and high saturation velocity of charge carriers, are particularly suitable for producing electronic components for power applications, such as MOSFET, JFET, HEMT (High Electron Mobility Transistors) and MISHEMT (Metal-Insulator-Semiconductor High Electron-Mobility Transistors).

A material having similar characteristics, and designed to be used for manufacturing electronic components, is silicon carbide (SiC) in its different polytypes (for example, 3C-SiC, 4H-SiC, 6H-SiC).

Another example of material, which is advantageously exploited for this purpose, is gallium nitride (GaN). For example, high-mobility field-effect transistors are known based on the formation of layers of two-dimensional electron gas (2DEG) with high mobility at a heterojunction, that is at the interface between semiconductor materials having different band gap. For example, HEMT transistors are known based on the heterojunction between a layer of aluminum gallium nitride (AlGaN) and a layer of gallium nitride (GaN).

In power transistors made of SiC or GaN, using high-permittivity dielectrics is advantageous to form insulating gate structures. In fact, these materials allow both the electric field inside the insulating gate structures and the on-state resistance RON of the devices to be reduced and, in addition, also entail benefits for the threshold voltage.

A problem of high-permittivity materials currently used is linked to the tendency to deteriorate when exposed to high temperatures. In particular, at temperatures commonly reached in some steps of the manufacturing of wide band gap devices, pure high-permittivity materials tend to crystallize and the phase change may lead to an increase in the leakage currents of the devices. For example, the formation of ohmic contacts typically include high-temperature annealing steps and may cause the crystallization of the high-permittivity dielectrics. Consequently, the process flow has to be organized so as to perform the steps that include high temperatures before forming the insulating gate structures. However, this process sequence may include additional steps otherwise unnecessary, which entail an increase in production costs. For example, an additional photolithography has to be performed to define the ohmic contacts separately from the insulating gate structure.

On the other hand, materials such as silicon oxide tolerate even very high temperatures without degrading, but do not have sufficient permittivity to achieve the high performances often desired.

### BRIEF SUMMARY

Various embodiments of the present disclosure provide a wide band gap transistor and a process for manufacturing a wide band gap transistor, which allow the limitations described to be overcome or at least mitigated.

The wide band gap transistor includes a semiconductor structure, having at least one wide band gap semiconductor layer of gallium nitride or silicon carbide; an insulating gate structure; and a gate electrode, separated from the semiconductor structure by the insulating gate structure. The insulating gate structure contains a mixture of aluminum, hafnium and oxygen.

### BRIEF DESCRIPTION OF THE SEVERAL VIEWS OF THE DRAWINGS

For a better understanding of the present disclosure, some embodiments thereof will now be described, purely by way of non-limiting example and with reference to the attached drawings, wherein:

FIG. 1 shows a cross-section through a wide band gap transistor according to an embodiment of the present disclosure;

FIG. 2a shows an enlarged detail of the transistor of FIG. 1 in a step of a process according to an embodiment of the present disclosure;

FIG. 2b shows the detail of FIG. 2a in a subsequent processing step;

FIG. 2c shows the detail of FIG. 2a in a subsequent processing step of a process according to a different embodiment of the present disclosure;

FIG. 3 shows a cross-section through a wide band gap transistor according to a different embodiment of the present disclosure;

FIGS. 4-8 show cross-sections through a semiconductor wafer during subsequent steps of a process according to a further embodiment of the present disclosure;

FIG. 9 shows a cross-section through a wide band gap transistor according to a further embodiment of the present disclosure;

FIG. 10 shows a cross-section through a semiconductor wafer during subsequent steps of a process according to yet another embodiment of the present disclosure;

FIG. 11 shows a cross-section through a wide band gap transistor according to a further embodiment of the present disclosure; and

FIGS. 12-16 show cross-sections through a semiconductor wafer during subsequent steps of a process according to a further embodiment of the present disclosure.

### DETAILED DESCRIPTION

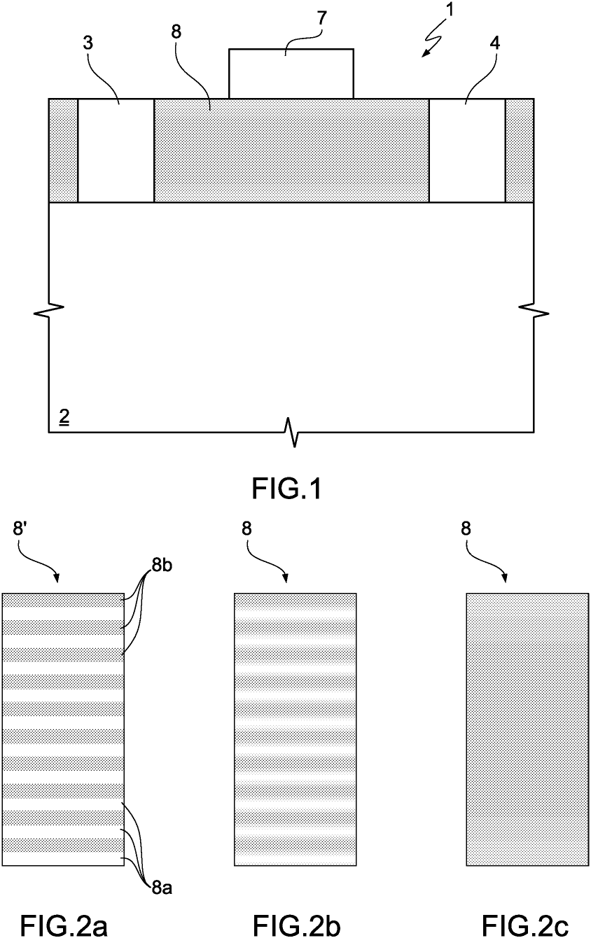

The present disclosure relates to the manufacture of insulating gate structures in particular in wide band gap transistors. FIG. 1 shows a cross-section through a wide band gap transistor according to an embodiment of the present disclosure. Referring to FIG. 1, in general, a wide band gap transistor 1 comprises a semiconductor structure 2, wherein at least one layer is of a wide band gap semiconductor material, such as gallium nitride (GaN) or silicon carbide (SiC), a source electrode 3, a drain electrode 4 and a gate electrode 7, separated from the semiconductor structure 2 by an insulating gate structure 8. More precisely, the semiconductor structure 2 may include, in case of a GaN HEMT device, an aluminum gallium nitride (AlGaN) and GaN heterostructure -AlGaN/GaN heterostructure - or, in case of a SiC MOSFET, a SiC substrate with a high doping level (e.g., 10¹⁸ atoms/cm³ or greater) and a SiC epitaxial layer with a lower doping level (e.g., 10¹⁵-10¹⁶ atoms/cm³). FIG. 2a shows an enlarged detail of the transistor of FIG. 1 in a step of a process according to an embodiment of the present disclosure; FIG. 2b shows the detail of FIG. 2a in a subsequent processing step; and FIG. 2c shows the detail of FIG. 2a in a subsequent processing step of a process according to a different embodiment of the present disclosure. The insulating gate structure 8, illustrated in greater detail in FIGS. 2a-2c, contains a mixture of aluminum, hafnium and oxygen. More precisely, the insulating gate structure 8 is obtained by the conformal deposition in alternated succession of a plurality of aluminum oxide layers 8a and a plurality of hafnium oxide layers 8b having nanometer thickness to form a gate stack 8′ (FIG. 2a), followed by an annealing step (FIGS. 2b, 2c). Stated differently, each of the plurality of aluminum oxide layers 8a is separated from another one of the plurality of aluminum oxide layers 8a by at least one of the plurality of hafnium oxide layers 8b. The aluminum oxide layers 8a and the hafnium oxide layers 8b may for example each have a thickness comprised between 0.5 nm and 10 nm, are amorphous and are obtained by Atomic Layer Deposition (ALD). In one embodiment, each of the aluminum oxide layers 8a and the hafnium oxide layers has a thickness between 1 nm and 5 nm. The number of layers 8a, 8b is determined so that an overall thickness of the insulating gate structure 8 has a desired value, for example comprised between 30 nm and 60 nm. In a non-limiting embodiment, all the aluminum oxide layers 8a and the hafnium oxide layers 8b have equal thickness.

During the annealing step, aluminum oxide and hafnium oxide diffuse at the interfaces between the layers 8a, 8b and mix. Therefore, the mixture of aluminum, hafnium and oxygen is present at least at the interfaces. According to the initial thickness of the aluminum oxide layers 8a and the hafnium oxide layers 8b, the duration and the temperature of the annealing step, in the final insulating gate structure 8, the starting layered structure may be partially preserved (see, for example, FIG. 2b) or, alternatively, may be lost (see, for example, FIG. 2c). For example, as shown in FIG. 2b, the interfaces between the aluminum oxide layers 8a and the hafnium oxide layers 8b are integrated or mixed with each other, while remaining portions of the aluminum oxide layers 8a and the hafnium oxide layers 8b remain the same. In contrast, as shown in FIG. 2c, the aluminum oxide layers 8a and the hafnium oxide layers 8b are completely integrated or mixed with each other such that the insulating gate structure 8 no longer has the layered structure. The annealing step may be carried out by heating the gate stack 8′ to an annealing temperature comprised between 500° C. and 950° C., preferably between 600° C. and 800° C., for example 800° C. The annealing duration may be comprised between 30 seconds and 600 seconds. The annealing temperature and the annealing duration are however selected so as to avoid crystallization of the insulating gate structure 8, owing to the diffusion and mixing of aluminum oxide and hafnium oxide. The permittivity and crystallization temperature of the insulating gate structure 8 are intermediate between the permittivity and the temperature of the aluminum oxide and those of the hafnium oxide. The insulating gate structure 8 has therefore satisfactory permittivity values and, at the same time, is capable of withstanding without structure alterations the thermal stresses that occur during the manufacturing steps of the power devices, for example for the formation of ohmic contacts. Since gate structures do not need to be protected from exposure to high temperatures, the process flow may be optimized so as to avoid unnecessary steps, for example by reducing the number of photolithographs.

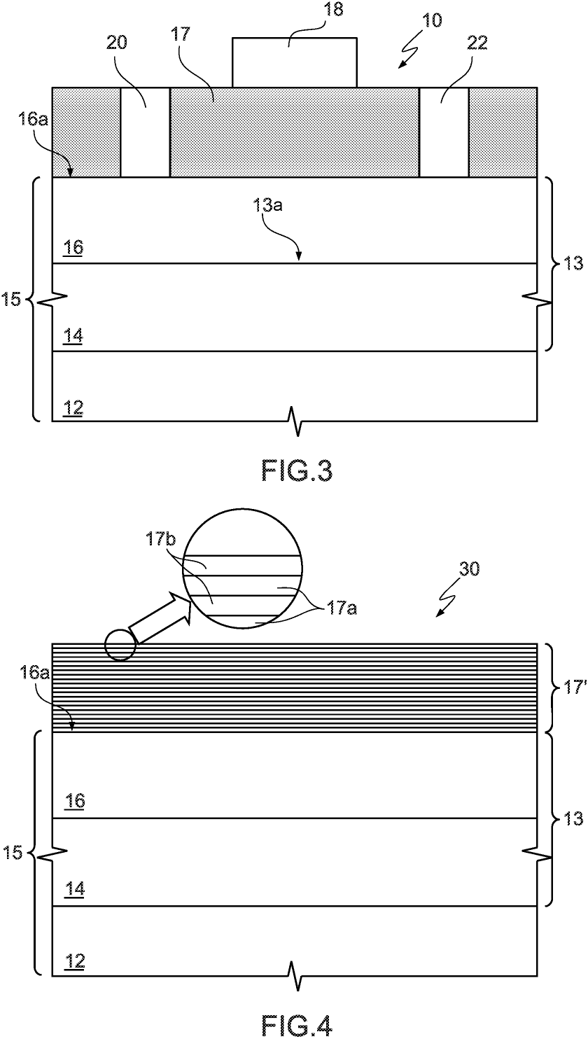

FIG. 3 shows a HEMT device 10 provided with an insulating gate structure obtained as described. The HEMT device 10 includes: a substrate 12, for example of silicon, or silicon carbide (SiC) or aluminum oxide (Al₂O₃); a channel layer 14, of intrinsic gallium nitride (GaN), extending on the substrate 12; a barrier layer 16, of intrinsic aluminum gallium nitride (AlGaN) or, more generally, of compounds based on ternary or quaternary alloys of gallium nitride, such as AlₓGa₁₋ₓN, AlInGaN, InₓGa₁₋ₓN, AlₓIn₁₋ₓAl, extending on the channel layer 14; an insulating gate structure 17, extending on a face 16a of the barrier layer 16 opposite to the channel layer 14; a gate electrode 18 extending on the insulating gate structure 17 between a source electrode 20 and a drain electrode 22.

The channel layer 14 and the barrier layer 16 form a heterostructure 13 with a heterojunction 13a at the interface to each other. The heterostructure 13 extends, therefore, between a bottom side of the channel layer 14, which is part of the interface with the underlying substrate 12, and a top side 16a of the barrier layer 16.

The substrate 12, the channel layer 14 and the barrier layer 16 are hereinafter referred to, as a whole, as semiconductor structure 15. An active region 13a, defined in the semiconductor structure 15, accommodates, in use, the conductive channel of the HEMT device 10. In the embodiment of FIG. 3, the gate electrode 18 extends on the insulating gate structure 17 in a zone corresponding to (e.g., directly overlying) the active region 13a.

The insulating gate structure 17, provided as already illustrated with reference to FIGS. 2a-2c, contains a mixture of aluminum, hafnium and oxygen. More precisely, the insulating gate structure 17 is obtained by the conformal deposition in alternated succession of a plurality of aluminum oxide layers 17a and a plurality of hafnium oxide layers 17b having nanometer or sub-nanometer thickness, followed by an annealing step. The aluminum oxide layers 17a and the hafnium oxide layers 17b are amorphous.

According to further embodiments not shown, the semiconductor body 15 and well as the active region 13a accommodated therein, may comprise, according to the design preferences, a single layer or multiple layers of GaN, or GaN alloys, suitably doped or of an intrinsic type.

In the embodiment of FIG. 3, the source 20 and drain electrodes 22, of conductive material, for example metal, extend exclusively through the insulating gate layer 17, until they reach the surface 16a of the barrier layer 16, without going deep into the barrier layer 16.

According to embodiments not shown, the source electrode 20 and the drain electrode 22 extend for a part of the thickness of the barrier layer 16, terminating inside the barrier layer 16.

According to further embodiments not shown, the source electrode 20 and the drain electrode 22 extend in depth into the semiconductor body 15, completely through the barrier layer 16, terminating at the interface between the barrier layer 16 and the channel layer 14.

According to further embodiments not shown, the source electrode 20 and the drain electrode 22 further extend partially through the channel layer 14 and terminate into the channel layer 14.

An example of a manufacturing process of the HEMT device 10 will be described below with reference to FIGS. 4-8. In particular, FIGS. 4-8 show cross-sections through a semiconductor wafer during subsequent steps of a process of manufacturing the HEMT device 10.

Initially, FIG. 4, a semiconductor wafer 30 comprises the substrate 12, for example of silicon or silicon carbide (SiC) or aluminum oxide (Al₂O₃). The channel layer 14, of gallium nitride (GaN), and the barrier layer 16, of aluminum gallium nitride (AlGaN), are formed on the substrate 12, extending on the channel layer 14. The barrier layer 16 and the channel layer 14 form, as previously mentioned, the heterostructure 13 and the heterojunction 13a.

A gate stack 17′ is then formed, as described with reference to FIG. 2a. In particular, the gate stack 17′ is obtained by the conformal deposition in alternated succession of a plurality of aluminum oxide layers 17a (Al₂O₃) and a plurality of hafnium oxide layers 17b (HfO₂) having nanometer or sub-nanometer thickness, until they reach a desired overall thickness. Stated differently, each of the plurality of aluminum oxide layers 17a is separated from another one of the plurality of aluminum oxide layers 17a by at least one of the plurality of hafnium oxide layers 17b. The aluminum oxide layers 17a and the hafnium oxide layers 17b are amorphous and are formed by Atomic Layer Deposition (ALD), which ensures structure conformality and extremely accurate thickness control.

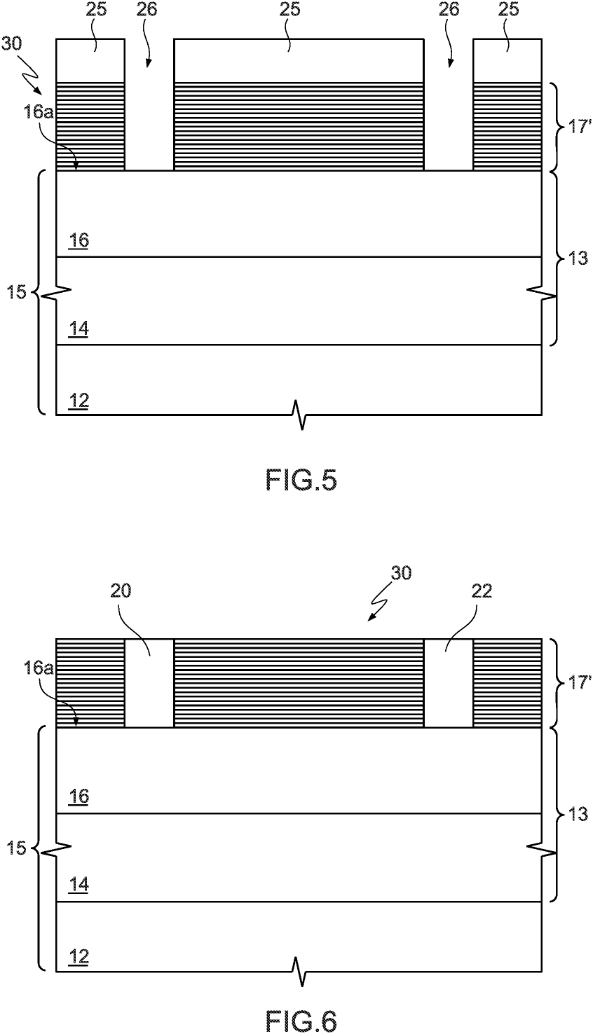

Subsequently (FIG. 5), a first sacrificial layer 25, for example of resist, is formed on the gate stack 17′ and defined by a first photolithographic process. The first sacrificial layer 25 has openings 26 for the formation of the source electrode 20 and of the drain electrode 22. The first sacrificial layer 25 is used as a mask to selectively etch the gate stack 17′ through the openings 26.

Referring to FIG. 6, following the deposition of a metal layer or multilayer and the lift-off of the first sacrificial layer 25, the source electrode 20 and the drain electrode 22 are formed in positions corresponding to respective openings 26.

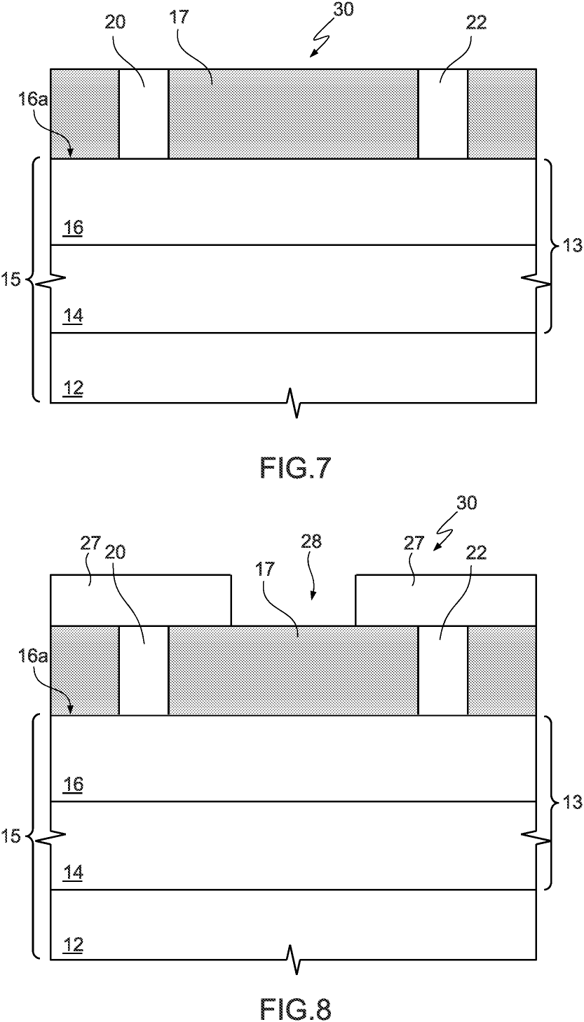

An annealing step is then performed at a temperature comprised for example between 500° C. and 950° C., preferably between 600° C. and 800° C., for the formation of ohmic contacts. At the same time, the aluminum oxide layers 17a and the hafnium oxide layers 17b that are adjacent diffuse into each other at the respective interfaces and the insulating gate structure 17 is formed from the residual portions of the gate stack 17′, as shown in FIG. 7. The number and thicknesses of the aluminum oxide layers 17a and the hafnium oxide layers 17b, the annealing temperature and the annealing duration are selected according to the design preferences so that the insulating gate structure 17 maintains (as in the example of FIG. 2b) or does not maintain traces (as in the example of FIG. 2c) of the starting layers 17a, 17b and crystallization is avoided.

A second sacrificial layer 27 (FIG. 8) is then formed on the insulating gate structure 17, on the source electrode 20 and on the drain electrode 22 and defined by a second photolithographic process. The second sacrificial layer 27 has an opening 28 for the formation of the gate electrode 18.

Following the deposition of a metal layer or multilayer and the lift-off by (plasm or wet) etching of the second sacrificial layer 27, the gate electrode 18 is formed in a position corresponding to the opening 28. Optionally, a further annealing step may be performed after the deposition of the metal layer or multilayer, for example at 400° C.

After conventional and not illustrated final processing steps and the dicing of the semiconductor wafer 30, the HEMT device 10 of FIG. 3 is obtained.

The diffusion of the aluminum oxide layers 17a and the hafnium oxide layers 17b during annealing allows a high permittivity value, typically intermediate between the permittivity values of the single intrinsic Al₂O₃ and HfO₂ layers, to be maintained, while avoiding crystallization of the material during subsequent high temperature processing steps. In particular, the resistance to high temperatures advantageously allows the gate stack 17′ to be formed before forming the source and drain electrodes with the respective ohmic contacts without the material being degraded. In this manner a single photolithographic process and a single annealing step may be used to both define the insulating gate structure 17 and to form the source and drain electrodes with the respective ohmic contacts.

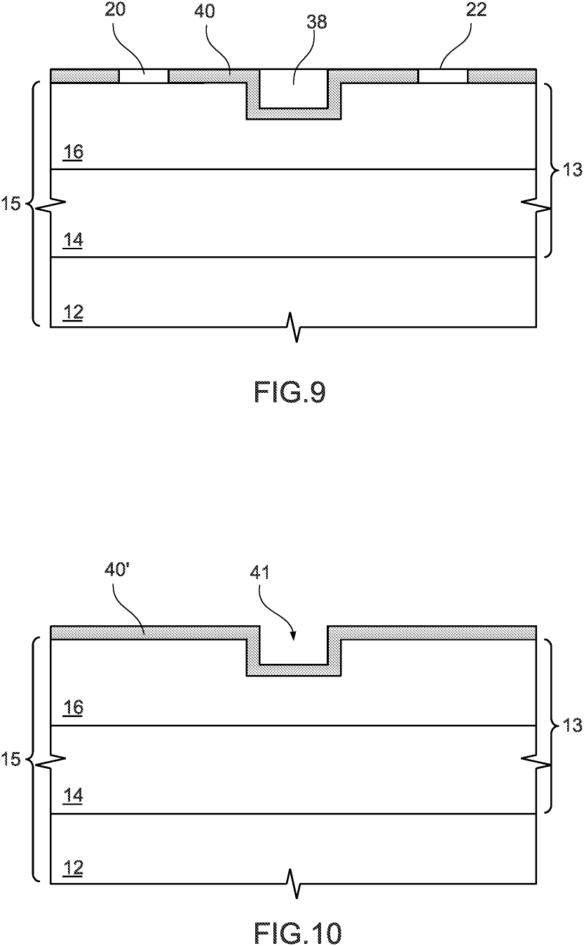

FIG. 9 shows a cross-section through a wide band gap transistor according to a further embodiment of the present disclosure. In FIG. 9, the gate region, here indicated by 38, may be of a recess type and insulating gate structure 40 is not planar.

FIG. 10 shows a cross-section through a semiconductor wafer during subsequent steps of a process of manufacturing the wide band gap transistor shown in FIG. 9. In this case, the barrier layer 16 is selectively plasma etched to open a trench 41 before forming the insulating multilayer 40′, which is conformally deposited by ALD. The gate region 38 is then formed in the trench 41 as shown in FIG. 9. Portions of the insulating multilayer 40′ are removed, and the source electrode 20 and the drain electrode 22 are then formed on the barrier layer 16 as shown in FIG. 9.

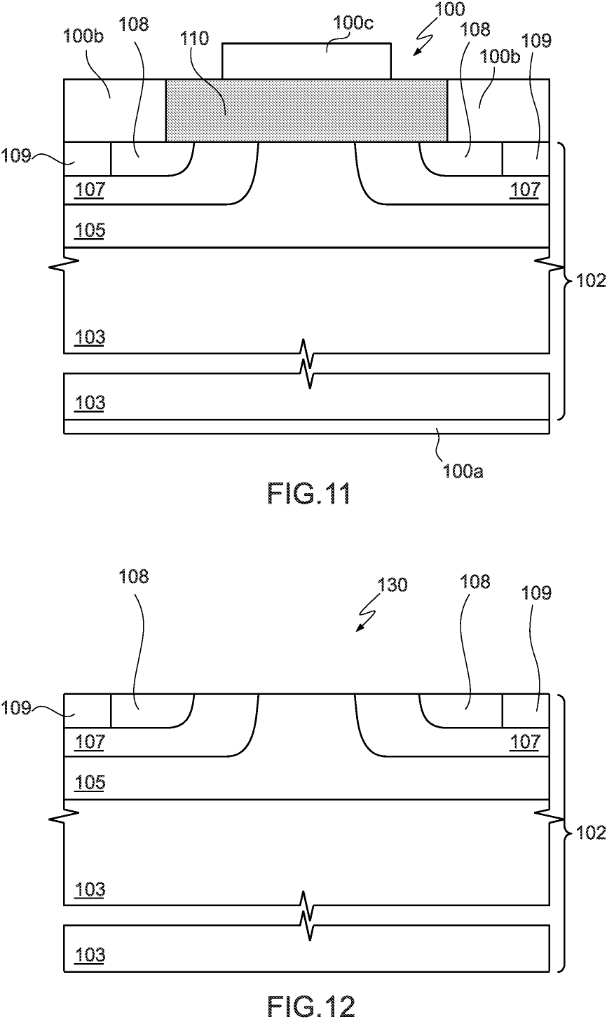

FIG. 11 shows a cross-section through a wide band gap transistor according to a further embodiment of the present disclosure. In particular, FIG. 11 shows a vertical MOSFET 100 that comprises a semiconductor structure 102 of silicon carbide (SiC), has a drain electrode 100a on a rear side 102a of the semiconductor structure 102 and source electrodes 100b and a gate electrode 100c on a front side 102b of the semiconductor structure 102. The semiconductor structure 102 in turn comprises a substrate 103 (one face whereof defines the rear side 100a) and an epitaxial layer 105 (one face whereof defines the front side 102b of the semiconductor structure 102) both having conductivities of a first type, for example of N-type. However, the N-type substrate 103 of SiC has a first doping level that is higher (e.g., 10¹⁸ atoms/cm³ or greater), while the epitaxial layer 103 has a second doping level that is lower (e.g., 10¹⁵-10¹⁶ atoms/cm³).

Body wells 107, having conductivity of a second type, here P-type, are formed inside the epitaxial layer 105 and accommodate respective source regions 108, with conductivity of the first type, in particular N+, and contact regions 109, with conductivity of the second type, in particular P+, and contiguous to respective source regions 108. The epitaxial layer 105 defines a Current Spread Layer (CSL) wherein the body wells 107 are embedded.

The body wells 107 are separated from each other by a distance normally less than 1 µm, for example 0.6 µm. The body wells 107 and the portion of the epitaxial layer 105 comprised therebetween form a parasitic JFET region.

An insulating gate structure 110 extends on the front side 102a of the semiconductor structure 102 on the epitaxial layer 105 (or on the enhancement layer 6, if any) between the source regions 108 and is surmounted by the gate electrode 100b. The insulating gate structure 110, provided as already illustrated with reference to FIGS. 2a-2c, contains a mixture of aluminum, hafnium and oxygen. More precisely, the insulating gate structure 110 is obtained by the conformal deposition in alternated succession of a plurality of aluminum oxide layers and a plurality of hafnium oxide layers having nanometer or sub-nanometer thickness, followed by an annealing step.

An example of a manufacturing process of the MOSFET 100 will be described below with reference to FIGS. 12-16. In particular, FIGS. 12-16 show cross-sections through a semiconductor wafer during subsequent steps of a process of manufacturing the MOSFET 100.

Initially, FIG. 12, a semiconductor wafer 130 comprises the substrate 103, whereon the epitaxial layer 105 is grown to form the semiconductor structure 102. The body wells 107, the source regions 108 and the contact regions 109 are then formed by subsequent ion implantations of different doping species. After the implantations, an activation annealing step is carried out at a high temperature, for example above 1600° C.

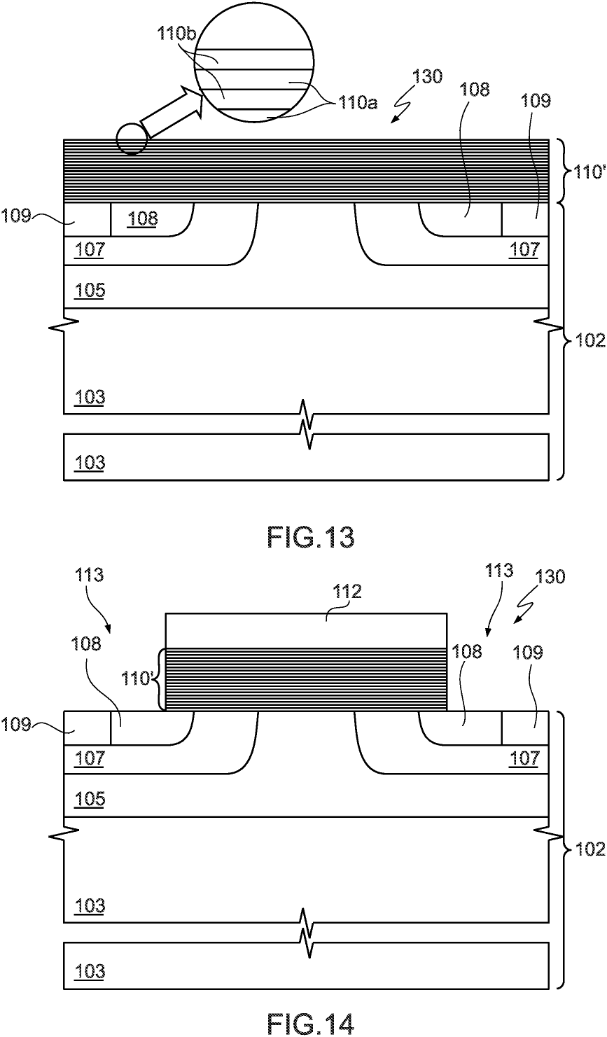

Then (FIG. 13), a gate stack 110′ is formed, as described with reference to FIG. 2a. In particular, the gate stack 110′ is obtained by the conformal deposition in alternated succession of a plurality of aluminum oxide layers 110a and a plurality of hafnium oxide layers 110b having nanometer thickness, until they reach an overall desired thickness. The aluminum oxide layers 110a and the hafnium oxide layers 110b are formed by Atomic Layer Deposition (ALD).

As shown in FIG. 14, a first sacrificial layer 112 of resist is formed on the gate stack 110′ and defined by a first photolithographic process. The first sacrificial layer 112 has openings 113 for the formation of the source electrodes 100b and is used as a mask to selectively etch the gate stack 110′.

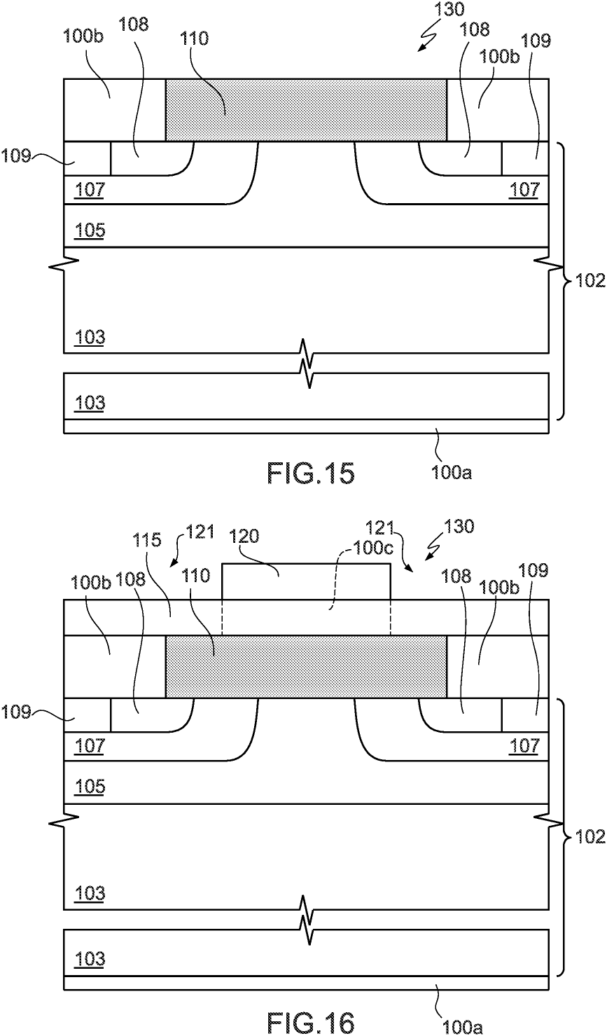

Referring to FIG. 15, following the deposition of a metal layer or multilayer on the front side 102b of the semiconductor structure 102 and the lift-off of the first sacrificial layer 112, the source electrodes 100b are formed in positions corresponding to respective openings 113. Simultaneously or subsequently to the deposition on the front side 102b, a metal layer or multilayer is also deposited on the rear side 102a of the semiconductor structure 102e to form the drain electrode 100a. Before depositing the drain electrode 100a, the substrate 103 may be mechanically thinned (grinded) and possibly be subject to laser annealing.

Once the drain electrode 100a and the source electrodes 100b have been formed, an annealing step is carried out, for example at an annealing temperature of 800° C. for the formation of silicides. In this step, wherein the gate stack 110′ is heated to the annealing temperature, the aluminum oxide and hafnium oxide of the layers 110a, 110b of the gate stack 110′ diffuse at the interfaces and mix. Thus, at least at the interfaces, the mixture of aluminum, hafnium and oxygen is present. According to the initial thickness of the aluminum oxide layers 110a and the hafnium oxide layers 110b, the duration and the temperature of the annealing step, in the final insulating gate structure 110, the starting layered structure may be partially preserved (as in the example of FIG. 2b) or, alternatively, may be lost (as in the example of FIG. 2c).

After annealing (FIG. 16), a metal layer or multilayer 115, of a material different from the material used for the source electrodes 100b, is deposited on the insulating gate structure 110 and on the source electrodes 100b, then a second sacrificial layer 120 of resist is formed on part of the metal layer or multilayer 115 and is defined by a second photolithographic process. The second sacrificial layer 120 has openings 121 for the formation of the gate electrodes 100c. The second sacrificial layer 120 is used as a mask to selectively etch the metal layer or multilayer 115 through the openings 121, for example by plasma etching. The gate electrode 100c is thus obtained.

After conventional and not illustrated final processing steps and the dicing of the semiconductor wafer 30, the MOSFET 100 of FIG. 11 is obtained.

The insulating gate structure 110 and the manufacturing process described allow high-permittivity dielectrics to be used as gate insulators in SiC MOSFETs instead of silicon oxide, for example, with a double advantage. On the one hand, in fact, the high permittivity allows the highest electric field values to be localized within the epitaxial layer 105. It is thus possible to optimize both the thickness of the same epitaxial layer 105 and the on-state resistance RON. On the other hand, the process flow is simplified because the nitric oxide post-oxidation annealing steps at high temperature (1100 - 1200° C.) are eliminated.

Finally, it is apparent that modifications and variations may be made to the described transistor and process, without departing from the scope of the present disclosure.

A wide band gap transistor may be summarized as including a semiconductor structure (2; 15; 102), including at least one wide band gap semiconductor layer (14, 16; 103, 105) of gallium nitride (GaN) or silicon carbide (SiC); an insulating gate structure (8; 17; 110); and a gate electrode (7; 18; 100c), separated from the semiconductor structure (2; 15; 102) by the insulating gate structure (8; 17; 110), wherein the insulating gate structure (8; 17; 110) contains a mixture of aluminum, hafnium and oxygen.

The semiconductor structure (15) may include a heterostructure (13) including a channel layer (14) of gallium nitride (GaN) and a barrier layer (16) of a material selected in the group consisting of aluminum gallium nitride (AlGaN), ternary alloys of aluminum and gallium or quaternary alloys of aluminum and gallium; and a heterojunction (13a) being formed at an interface between the channel layer (14) and the barrier layer (16).

The semiconductor structure (102) may include a substrate (103) of silicon carbide (SiC) having a conductivity of a type and a first doping level; and an epitaxial layer (105) of silicon carbide (SiC) having conductivity of said type and a second doping level lower than the first doping level.

The insulating gate structure (8; 17; 110) may be at least partially layered in a plurality of first regions (8a; 17a) containing aluminum oxide (Al₂O₃) and a plurality of second containing regions (8b; 17b) of hafnium oxide (HfO₂) that are alternated with the first regions (8a; 17a).

The first regions (2a; 17a) and the second containing regions (8b; 17b) may have a thickness between 1 nm and 5 nm.

The insulating gate structure (8; 17; 110) may be amorphous.

A process for manufacturing a wide band gap transistor may be summarized as including forming a semiconductor structure (2; 15; 102), including at least one wide band gap semiconductor layer (14, 16; 103, 105) of gallium nitride (GaN) or silicon carbide (SiC); forming an insulating gate structure (8; 17; 110) on the semiconductor structure (2; 15; 102); and forming a gate electrode (7; 18; 100c) on the insulating gate structure (8; 17; 110), wherein the insulating gate structure (8; 17; 110) contains a mixture of aluminum, hafnium and oxygen.

Forming the semiconductor structure (2; 15; 102) may include forming a heterostructure (13) including a channel layer (14) of gallium nitride (GaN) and a barrier layer (16) of aluminum gallium nitride (AlGaN), a heterojunction (13a) being formed at an interface between the channel layer (14) and the barrier layer (16).

Forming the semiconductor structure (102) may include forming a substrate (103) of silicon carbide (SiC) having a conductivity of a type and a first doping level; and forming an epitaxial layer (105) of silicon carbide (SiC) having conductivity of said type and a second doping level lower than the first doping level.

Forming the insulating gate structure (8; 17; 110) may include depositing in alternated succession a plurality of aluminum oxide layers (8a; 17a; 110a) and a plurality of hafnium oxide layers (8b; 17b; 110b), forming a gate stack (8′; 17′; 110′); and performing an annealing so that the aluminum oxide of the aluminum oxide layers (8a; 17a; 110a) and the hafnium oxide of the hafnium oxide layers (8b; 17b; 110b) diffuse at interfaces between adjacent aluminum oxide layers (8a; 17a; 110a) and hafnium oxide layers (8b; 17b; 110b) and mix.

Performing an annealing may include heating the gate stack (8′; 17′; 110′) to an annealing temperature for an annealing duration and the annealing temperature and the annealing duration may be selected so as to prevent the insulating gate structure (8; 17; 110) from crystallizing.

The temperature may be between 500° C. and 950° C., preferably between 600° C. and 800° C., and the annealing duration may be between 30 s and 600 s.

Depositing in succession may include depositing by Atomic Layer Deposition (ALD).

The aluminum oxide layers (8a; 17a; 110a) and the hafnium oxide layers (8b; 17b; 110b) may have a thickness between 0.5 nm and 10 nm.

The process may include forming at least one source electrode (3; 20; 100b) and a drain electrode (4; 20; 100a), after forming the gate stack (8′; 17′; 110′).

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A wide band gap transistor, comprising:
a semiconductor structure including at least one wide band gap semiconductor layer of gallium nitride (GaN) or silicon carbide (SiC);
an insulating gate structure on the semiconductor structure; and
a gate electrode on the insulating gate structure and separated from the semiconductor structure by the insulating gate structure,
the insulating gate structure including a mixture of aluminum, hafnium, and oxygen.

2. The wide band gap transistor according to claim 1, wherein the semiconductor structure includes a heterostructure including:
a channel layer of gallium nitride (GaN);
a barrier layer of a material selected from a group of materials including: aluminum gallium nitride (AlGaN), ternary alloys of aluminum and gallium, and quaternary alloys of aluminum and gallium; and
a heterojunction being formed at an interface between the channel layer and the barrier layer.

3. The wide band gap transistor according to claim 1, wherein the semiconductor structure includes:
a substrate of silicon carbide (SiC) having a conductivity type and a first doping level; and
an epitaxial layer of silicon carbide (SiC) having the conductivity type and a second doping level lower than the first doping level.

4. The wide band gap transistor according claim 1, wherein the insulating gate structure is at least partially layered with a plurality of first regions including aluminum oxide (A1₂O₃) and a plurality of second containing regions including hafnium oxide (HfO₂) that are alternated with the first regions.

5. The wide band gap transistor according to claim 4, wherein each of the first regions and each of the second containing regions has a thickness comprised between 1 nm and 5 nm.

6. The wide band gap transistor according to claim 1, wherein the insulating gate structure is amorphous.

7. A process for manufacturing a wide band gap transistor, the process comprising:
forming a semiconductor structure including at least one wide band gap semiconductor layer of gallium nitride (GaN) or silicon carbide (SiC);
forming an insulating gate structure on the semiconductor structure; and
forming a gate electrode on the insulating gate structure,
the insulating gate structure including a mixture of aluminum, hafnium, and oxygen.

8. The process according to claim 7, wherein forming the semiconductor structure includes:
forming a heterostructure including:
a channel layer of gallium nitride (GaN); and
a barrier layer of aluminum gallium nitride (AlGaN), a heterojunction being formed at an interface between the channel layer and the barrier layer.

9. The process according to claim 7, wherein forming the semiconductor structure includes:
forming a substrate of silicon carbide (SiC) having a conductivity type and a first doping level; and
forming an epitaxial layer of silicon carbide (SiC) having the conductivity type and a second doping level lower than the first doping level.

10. The process according to claim 7, wherein forming the insulating gate structure includes:
depositing, in alternated succession, a plurality of aluminum oxide layers and a plurality of hafnium oxide layers, forming a gate stack; and
performing an annealing such that aluminum oxide of the plurality of aluminum oxide layers and hafnium oxide of the plurality of hafnium oxide layers diffuse at interfaces between adjacent aluminum oxide layers and hafnium oxide layers and mix.

11. The process according to claim 10, wherein
performing the annealing includes heating the gate stack to an annealing temperature for an annealing duration, and
the annealing temperature and the annealing duration are selected so as to prevent the insulating gate structure from crystallizing.

12. The process according to claim 11, wherein the annealing temperature is between 500° C. and 950° C., and the annealing duration is between 30 seconds and 600 seconds.

13. The process according to claim 10, wherein depositing in succession include depositing by Atomic Layer Deposition.

14. The process according to claim 10, wherein each of the plurality of aluminum oxide layers and each of the plurality of hafnium oxide layers have a thickness comprised between 0.5 nm and 10 nm.

15. The process according to claim 10, further comprising:
forming at least one source electrode and a drain electrode, after forming the gate stack.

16. A method, comprising:
forming a semiconductor structure including gallium nitride (GaN) or silicon carbide (SiC);
forming an insulating gate structure on the semiconductor structure, the forming of the insulating gate structure including:
forming a first plurality of layers of aluminum oxide (Al₂O₃); and
forming a second plurality of layers of hafnium oxide (HfO₂); and
forming a gate electrode on the insulating gate structure.

17. The method of claim 16, further comprising:
annealing the first plurality of layers and the second plurality of layers.

18. The method of claim 17, wherein the annealing is performed at an annealing temperature for an annealing duration, and the annealing temperature and the annealing duration are selected to prevent the insulating gate structure from crystallizing.

19. The method of claim 16, wherein each of the first plurality of layers is spaced from another layer of the first plurality of layers by a layer of the second plurality of layers.

20. The method of claim 16 wherein forming the semiconductor structure includes forming a channel layer on a substrate, and forming a barrier layer on the channel layer.
